(19) United States
(12) Patent Application Publication
(10) Pub. No.: US 2025/0301598 A1
(43) Pub. Date: Sep. 25, 2025

(54) AUXILIARY COOLING SYSTEM FOR DASHCAMS

(71) Applicant: Nexar Ltd., Tel Aviv (IL)

(72) Inventors: Lev Yitzhak Lavy, Misgav Dov (IL); Ruben Alexandre Sequeira Sarmento, Porto (PT); Likhon Roy, Atlanta, GA (US)

(21) Appl. No.: 19/221,826

(22) Filed: May 29, 2025

(51) Int. Cl. H05K 7/20; B60R 1/24

(52) U.S. Cl. CPC H05K 7/20209; H05K 7/20154; H05K 7/20172; B60R 1/24

(57) ABSTRACT

An auxiliary cooling system for dashcams includes a variable speed fan attachable to a dashcam, a thermostat for temperature monitoring, and a pass-through power connector. The pass-through connector allows the system to draw power from the dashcam's power source while ensuring continued power delivery to the dashcam. Fan speed is controlled based on temperature readings, potentially with hysteresis, to optimize cooling and minimize noise. Optional features include an open design for easy cleaning, flat or transparent cabling for concealed installation, an integrated UPS for backup power, multiple thermostats for improved accuracy, an integrated USB hub, and sensor-based feedback (microphone, accelerometer) for intelligent fan speed adjustment. The system aims to enhance dashcam reliability and performance, especially in high-temperature environments or under heavy processing loads, by providing active thermal management.

### FIELD OF THE INVENTION

The present invention relates to thermal management for electronic devices, and more specifically to an auxiliary cooling system for dashboard cameras, referred to as dashcams.

### BACKGROUND OF THE INVENTION

Conventional dashcams typically rely on passive cooling mechanisms to dissipate heat generated during operation. While this approach has traditionally been sufficient for devices with limited functionality and low power consumption, modern dashcams increasingly incorporate high-performance features. These features include inter alia high-resolution 4K video recording, wireless connectivity, e.g., Wi-Fi, Bluetooth, cellular, artificial intelligence (AI) processing for tasks like object detection or driver monitoring, global navigation satellite system (GNSS) tracking, and other computationally intensive tasks. These enhancements significantly elevate the device's power consumption and, consequently, its thermal output.

Moreover, dashcams are often installed in vehicles that are parked in high-temperature environments for extended durations, such as under direct sunlight. In such cases, even when the vehicle is stationary, continuous functions like parking mode surveillance recording, connectivity maintenance for remote access, or cloud synchronization demand that the device remains powered and operational. This continuous operation further exacerbates thermal management challenges.

The combination of increased internal heat generation and high ambient temperatures can lead to several issues when only passive cooling is available. These issues include performance degradation, e.g., reduced processing speed and/or dropped frames in video recording, temporary thermal shutdowns to prevent damage, or even long-term component damage due to sustained high temperatures.

Existing solutions for cooling portable electronics, such as some mobile phone coolers, often either act as a full mount, are bulky, or occupy essential ports, e.g., a USB port, thereby reducing the functionality of the host device. For instance, some solutions block data communication capabilities if a dashcam uses its USB port for features like connecting to an On-Board Diagnostics (OBD) system or an external rear camera. Other solutions might offer wireless charging, which can itself contribute to overheating, requiring the fan to work harder and potentially create more noise. These solutions often lack an intelligent feedback loop for minimizing power consumption and noise pollution tailored to the specific needs of a dashcam.

As such, there is a need for an improved thermal management solution for modern dashcams that is efficient, minimally intrusive, and adaptable to varying operational and environmental conditions.

### SUMMARY

The present invention, hereinafter referred to as “Coolada,” provides an auxiliary cooling system specifically designed for dashcams and similar portable electronic devices. Coolada is embodied as an add-on accessory that delivers active thermal management and is designed to operate with a degree of independence from the dashcam's internal systems, while intelligently interfacing with its power source.

In one embodiment, the Coolada device includes an active cooling element, such as a low-noise variable-speed fan, and an attachment mechanism, such as an adhesive layer, for securing it to the surface of a dashcam, preferably on or near its hottest area. The system includes at least one thermal sensor/thermostat to monitor temperature. This temperature data is used to control the fan's operation.

A key feature is a pass-through power connector. This connector allows Coolada to draw power from the dashcam's existing power source, e.g., its USB input cable, without interrupting the power supply to the dashcam itself. The pass-through design ensures that the dashcam continues to receive power and, if applicable, data connectivity through its original port. A short cable connects the pass-through connector component to the main body of the Coolada, which houses the fan.

To ensure efficient thermal regulation and minimal noise generation, Coolada utilizes a fan controller. This controller is governed by a dedicated low-cost microcontroller unit (MCU) or a simpler hardware-based thermostat circuit. The controller adjusts the fan speed dynamically based on temperature readings from the thermostat(s), aiming to maintain optimal device operating conditions without generating excessive noise or consuming unnecessary power. The fan logic includes, e.g., hysteresis, starting the fan at a first, higher temperature, e.g., 75° C., and stopping it when the temperature falls below a second, lower temperature, e.g., 70° C.

The system is designed to be a low-cost scalable solution for enhancing thermal management in modern dashcam systems. It improves reliability and performance under both idle and high-load conditions, including scenarios where the vehicle is parked in extreme climates. The power consumption of the fan is intentionally limited to a fraction of the dashcam's total power consumption to prevent significant voltage drops to the dashcam.

Optional features and alternative embodiments include:
an open design for the fan housing to facilitate easy cleaning and maintenance;
use of flat cables, potentially with adhesive backing or transparent/semi-transparent materials, for improved aesthetics and concealed installation;
an integrated Uninterruptible Power Supply (UPS) module, allowing Coolada to provide backup power to both the fan and the dashcam during power interruptions or to manage peak power demands;
multiple thermostats, for instance, one at the connector, to infer internal device temperature, and another near the fan, to measure the direct cooling effect on the surface;
an integrated USB hub, either in the pass-through connector or in the main fan body, for users requiring additional USB ports;
feedback mechanisms involving a microphone, to adjust fan speed based on ambient noise, and/or an accelerometer, to differentiate between driving and parked modes for noise level adjustments;
cooling ribs integrated into the design for enhanced passive heat dissipation in conjunction with active fan cooling;
a metal base for the fan assembly to help reduce Electromagnetic Interference (EMI); and
an alternative attachment mechanism where the structure of the Coolada is shaped to snap onto the dashcam body.

The invention aims to address the deficiencies of purely passive cooling in modern, high-power dashcams and the limitations of existing active cooling accessories.

### BRIEF DESCRIPTION OF THE DRAWINGS

FIG. 1 is a general schematic view of an exemplary Coolada auxiliary cooling device, in accordance with an embodiment of the present invention;

FIG. 2 is a thermal image illustrating heat distribution on a Nexar dashcam operating at room temperature, indicating potential hot spots where an auxiliary cooler is beneficial and showing temperature correlation at the connector; and

FIG. 3 is a schematic diagram illustrating an exemplary installation instruction of the Coolada device with a dashcam and its power source, in accordance with an embodiment of the present invention.

### DETAILED DESCRIPTION

The present invention, Coolada, is an auxiliary cooling system designed to enhance the thermal management of dashcams and similar electronic devices prone to overheating.

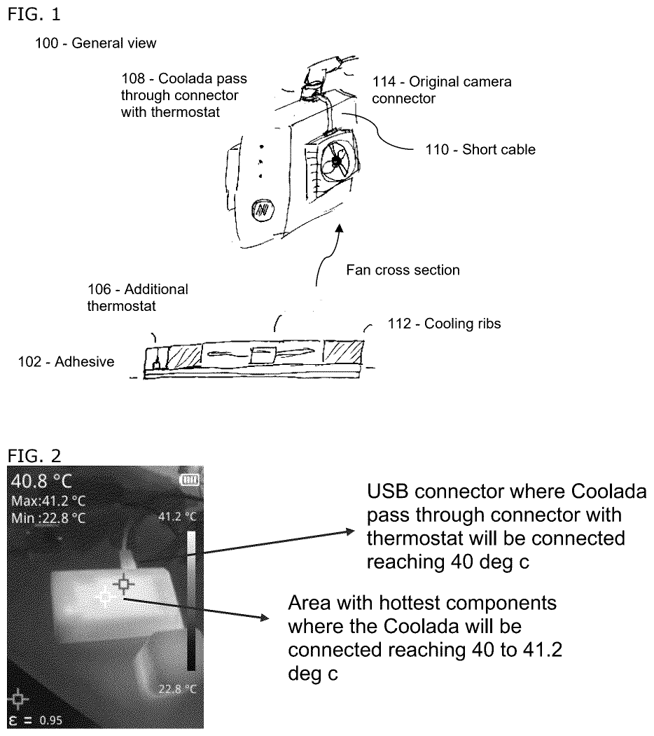

Reference of made to FIG. 1, which is a general schematic view of an exemplary Coolada auxiliary cooling device 100, in accordance with an embodiment of the present invention. The main components typically include an adhesive layer 102, or other attachment means, for securing the device to a dashcam, a low-noise, variable-speed fan 104, at least one thermostat 108/106, which is either integrated with a controller or is a separate component, a pass-through connector assembly 108, a short cable 110 connecting pass-through connector 108 to the fan assembly, and optionally, cooling ribs 112 on the fan housing or a heatsink element.

Fan 104 is designed for active cooling. From experiments, it has been observed that even a low-power, e.g., 30-50 mW, active fan provides significantly more effective cooling compared to passive cooling alone, especially in environments typical for dashcams, which often involve stagnant air, even with vehicle air conditioning running, and direct sun exposure. In one embodiment of the present invention, the fan's speed is variable, adjusted based on temperature readings from thermostat 106 or 108 to optimize cooling performance while minimizing noise and power consumption. In one embodiment of the present invention, fan 104 has a metal base or enclosure to reduce Electromagnetic Interference (EMI).

Thermostat 106/108 measures temperature to trigger and control fan 104. The fan logic is programmed or designed to operate independently of any software or activation from the dashcam itself. The fan logic incorporates, e.g., hysteresis, such as activating the fan when the sensed temperature reaches 75° C. and deactivating it when the temperature drops below 70° C. The positioning of the Coolada, and thus the primary thermostat, is on or near the hottest surface of the dashcam.

Reference is made to FIG. 2, which is a thermal image illustrating heat distribution on a Nexar dashcam operating at room temperature, indicating potential hot spots where an auxiliary cooler will be beneficial and showing temperature correlation at the connector. This image demonstrates that the connector area reflects the internal temperature of the dashcam. Thus, in one embodiment, thermostat 106, or one of the thermostats, if multiple are used, is located within or near pass-through connector assembly 108. This placement allows the system to measure an indirect temperature that is correlated with the dashcam's internal temperature, creating a feedback loop where fan speed adjusts based on the device's thermal state. For the thermostat to be most effective when measuring surface temperature, it is designed to have direct physical contact with the dashcam surface.

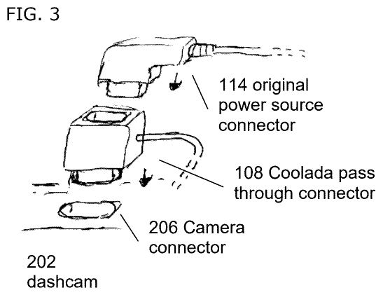

Pass-through connector assembly 108 is a critical component. FIG. 3 is a schematic diagram illustrating an exemplary installation instruction of Coolada device 100 with a dashcam and its power source, in accordance with an embodiment of the present invention. Coolada device connector 108 is installed between dashcam 202 and its usual power source 114, e.g., a USB car adapter. Power source 114 connects to the input of pass-through connector 108, which then provides a power output to dashcam 202, effectively “latching” onto the power line. Coolada 100 draws its own operational power from this latched connection. This arrangement ensures that the dashcam's power and data, if applicable, e.g., USB data, pathways remain functional.

To avoid causing a significant voltage drop to dashcam 202, the power consumption of fan 104 and its associated control circuitry is designed to be very low, typically a small fraction of the dashcam's overall power consumption. This aligns with the concept of overheating; namely, when the dashcam consumes more power and generates more heat, a slight increase in the fan's power draw is less likely to cause a critical voltage drop. Optionally, the system measures the voltage supplied to the dashcam with and without the fan active to dynamically adjust fan operation, though this is not mandatory if power consumption is appropriately capped and other system parameters are known.

### ALTERNATIVE EMBODIMENTS AND FEATURES

Flat Cable and Connector Design: In one embodiment of the present invention, cable 110 connecting pass-through connector 108 to the fan assembly is a flat cable. One side of this flat cable features an adhesive backing for improved visual concealment and neater installation. The flat cable is made from transparent or semi-transparent plastics to further reduce its visibility when installed. The pass-through connector itself is designed to allow the fan cable to route directly to the desired location on the dashcam.

Uninterruptible Power Supply (UPS): In one embodiment of the present invention, Coolada incorporates an integrated UPS module. This module contains a small battery. If the primary power to the dashcam is lost, e.g., vehicle engine off without a parking mode hardwire kit, or a power glitch, the UPS provides temporary power to both the dashcam and the Coolada's fan. This design helps manage extreme heat peaks by ensuring continuous cooling operation without causing voltage sags to the dashcam. Implementing this feature typically requires the power lines from the pass-through connector's input to route through the UPS module within Coolada before reaching the dashcam, rather than a direct pass-through.

Open Design: To facilitate easy maintenance and cleaning, e.g., dust removal from the fan, the fan assembly housing has an open or easily openable design. If fan 104 is made of soft material and operates at low RPM, it might be safe to touch even while operating. An open design also simplifies manufacturing and reduce costs.

Multiple Thermostats: For more robust and accurate temperature regulation, Coolada employs multiple thermostats. For example, an additional thermostat is placed directly adjacent to fan 104 to measure its direct impact on the dashcam surface temperature. After an initial cooling calibration, data from multiple thermostats allows for better prediction and control of the dashcam's internal temperature, especially in scenarios where a thermostat in connector 108 might not perfectly correlate with the internal temperature, e.g., if the connector is part of a separate mounting piece that is thermally isolated.

USB Hub: If the dashcam supports USB On-The-Go (OTG) or if users require additional USB ports, e.g., for charging another device or connecting another USB accessory, an embodiment of Coolada integrates a USB hub. This hub is incorporated into pass-through connector assembly 108 or within the main body housing fan 104. This would typically involve adding a USB hub integrated circuit (IC) to the Coolada's electronics.

Microphone and Accelerometer Feedback: To minimize audible noise pollution while maximizing cooling, the fan speed control logic incorporates feedback from additional sensors. A simple microphone is included, and its input used to adjust fan speed. For example, the fan increases speed during periods of high ambient noise, e.g., when driving on a rough road, with windows open, or music playing loudly, and reduces speed or operates more quietly when the ambient noise is low. An accelerometer is used to detect the vehicle's state: driving versus parked/idle. When the vehicle is parked and the driver is likely not present, noise limitations for the fan are relaxed. Other sensors are added for more intelligent operation.

Snap-on Attachment: As an alternative to adhesive 102, the physical structure of the Coolada device, e.g., the fan housing or a mounting bracket, is custom-shaped to snap directly onto the chassis or body of a specific dashcam model or a range of dashcams with similar form factors.

### Exemplary Implementation

An illustrative, non-limiting embodiment of the Coolada's electronics includes the following components:
Microcontroller Unit (MCU): e.g., ESP32 S3. Responsible for reading sensor data, implementing control logic (hysteresis, fan speed curves), and managing optional features like HID communication or sensor fusion.
RPM Controller: e.g., EMC2302-1-AIZL-TR. A dedicated IC for precise fan speed control.
Thermostat(s): e.g., TMP302ADRLR. Analog or digital temperature sensors.
DC-DC Converter: e.g., MIE1W0505BGLVH-3R-P, if fan voltage differs from logic voltage, and potentially a 3.3V DC-DC converter to power the MCU, RPM controller, and thermostat from the input USB voltage, typically 5V.
Fan: e.g., a small, low-power brushless DC fan, such as one similar to ADAFRUIT 4468, but preferably custom-made to be of soft material if an open design is used, and potentially with an integrated metallic enclosure that serves as a heatsink with cooling ribs.

Power is typically drawn from the USB-C, or other type, input connector of the dashcam as a parallel connection, ensuring the Coolada board takes minimal current from the input power supplied to the dashcam.

This detailed description is provided to enable any person skilled in the art to make and use the invention and sets forth the best modes contemplated by the inventors for carrying out their invention. Various modifications, however, will remain readily apparent to those skilled in the art, since the generic principles of the present invention have been defined herein specifically to provide an auxiliary cooling system for dashcams.

What is claimed is:

1. An accessory for cooling a dashcam, comprising:
a variable speed fan for active cooling;
an adhesive component for attaching said fan to a dashcam;
a thermostat for measuring temperature;
a pass-through connector receiving power from a power source of said dashcam and to provide power to the dashcam, wherein the accessory draws operational power from the dashcam power source via the pass-through connector;
a cable connecting said pass-through connector and said variable speed fan; and
cooling ribs associated with said fan for heat dissipation.

2. The accessory of claim 1, wherein said variable speed fan operates based on temperature readings from the thermostat, adjusting fan speed to maintain an optimal dashcam temperature.

3. The accessory of claim 2, wherein said thermostat and the associated control logic implement hysteresis in operation, activating said fan at a first temperature and deactivating it at a second, lower temperature.

4. The accessory of claim 1, wherein said cable is a flat cable with adhesive on one side for visual concealment during installation.

5. The accessory of claim 1, further comprising an integrated Uninterruptible Power Supply (UPS) module providing backup power to the dashcam and to said fan.

6. The accessory of claim 1, comprising an open design for the fan housing to facilitate easy maintenance and cleaning.

7. The accessory of claim 1, comprising multiple thermostats, including at least one thermostat positioned near said fan, to improve temperature measurement accuracy and control.

8. The accessory of claim 1, further comprising an integrated USB hub located within said pass-through connector or within a main body housing said fan.

9. The accessory of claim 1, further comprising a microphone integrated into a fan speed feedback loop, adjusting fan speed based on ambient noise levels.

10. The accessory of claim 1, further comprising an accelerometer detecting a vehicle operation mode, selected from the group consisting of driving and parked, and adjusting fan noise limitations accordingly.

11. The accessory of claim 1, wherein the power consumption of said fan is limited to a predetermined portion of the dashcam's power consumption to avoid significant voltage drop to the dashcam.

12. The accessory of claim 1, wherein said fan comprises a metal base or enclosure to reduce Electromagnetic Interference (EMI).

13. The accessory of claim 1, wherein said cable is a flat cable comprising transparent or semi-transparent plastic material to reduce visibility.

14. An accessory for cooling a dashcam, comprising:
a variable speed fan for active cooling;
a structure to snap on to a dashcam;
a thermostat for measuring temperature;
a pass-through connector receiving power from a power source of the dashcam and to provide power to the dashcam, wherein the accessory draws operational power from the dashcam power source via the pass-through connector;
a cable connecting said pass-through connector and said variable speed fan; and
cooling ribs associated with said fan for heat dissipation.
